(19) United States
(12) Patent Application Publication
(10) Pub. No.: US 2012/0002386 A1
(43) Pub. Date: Jan. 5, 2012

(54) Method and Apparatus for Improving the Reliability of Solder Joints

(75) Inventors: Lasse Juhani Pykari, Salo (FI); David L. Lu, Flower Mound, TX (US)

(73) Assignee: NOKIA CORPORATION, Espoo (FI)

(21) Appl. No.: 12/828,907

(22) Filed: Jul. 1, 2010

(51) Int. Cl. H05K 7/00; H05K 3/34

(52) U.S. Cl. 361/760; 361/783; 29/840; 29/841

(57) ABSTRACT

In accordance with an example embodiment of the present invention, a method, comprises receiving an integrated circuit component comprising at least one solder ball substantially surrounded by a first epoxy flux, applying a second epoxy flux to at least one integrated circuit component contact point of a printed circuit board, and performing a reflow process such that the integrated circuit component adheres to the printed circuit board and the first and second epoxy flux forms an encapsulating layer around at least one solder joint.

### TECHNICAL FIELD

The present application relates generally to a method and apparatus for improving the reliability of solder joints.

### BACKGROUND

In the field of surface-mount circuit board manufacturing, components are placed on pads or lands on the outer surfaces of the printed circuit board and then electrically and mechanically coupled to the circuit board with molten metal solder. There are a variety of soldering techniques used to attach components to printed circuit boards. High-volume production of circuit boards is usually accomplished using machine placement and bulk wave soldering or reflow ovens.

### SUMMARY

Various aspects of examples of the invention are set out in the claims.

According to a first aspect of the present invention, a method comprises receiving an integrated circuit component comprising at least one solder ball substantially surrounded by a first epoxy flux, applying a second epoxy flux to at least one integrated circuit component contact point of a printed circuit board and performing a reflow process such that said integrated circuit component adheres to the printed circuit board and the first and second epoxy flux forms an encapsulating layer around at least one solder joint.

According to a second aspect of the present invention, a method comprises applying epoxy flux to an interposer of an integrated circuit component and placing at least one solder ball on the interposer.

According to a third aspect of the present invention, an apparatus comprises at least one solder joint coupled with a printed circuit board, the solder joint being substantially encapsulated by epoxy flux.

### BRIEF DESCRIPTION OF THE DRAWINGS

For a more complete understanding of example embodiments of the present invention, reference is now made to the following descriptions taken in connection with the accompanying drawings in which:

FIG. 1 is a block diagram of an apparatus comprising an integrated circuit component, printed circuit board and a solder joint coupling the integrated circuit component and printed circuit board according to an example embodiment of the invention;

FIG. 2 is a block diagram of the apparatus of FIG. 1 further comprising the solder joint being encapsulated by epoxy flux according to an example embodiment of the invention;

FIG. 3 is a block diagram of an integrated circuit component comprising a plurality of solder balls substantially surrounded by epoxy flux according to an example embodiment of the invention;

FIG. 4 is a block diagram of the integrated circuit component of FIG. 3 and a printed circuit board having at least one integrated circuit contact point with epoxy flux disposed thereon according to an example embodiment of the invention;

FIG. 5 is a block diagram of an apparatus, the apparatus comprising an integrated circuit component comprising at least one solder joint coupled with a printed circuit board, the at least one solder joint being substantially encapsulated by epoxy flux according to an example embodiment of the invention; and

FIG. 6 is a flow diagram illustrating a method for coupling at least one integrated circuit component with a printed circuit board according to an example embodiment of the invention.

### DETAILED DESCRIPTION OF THE DRAWINGS

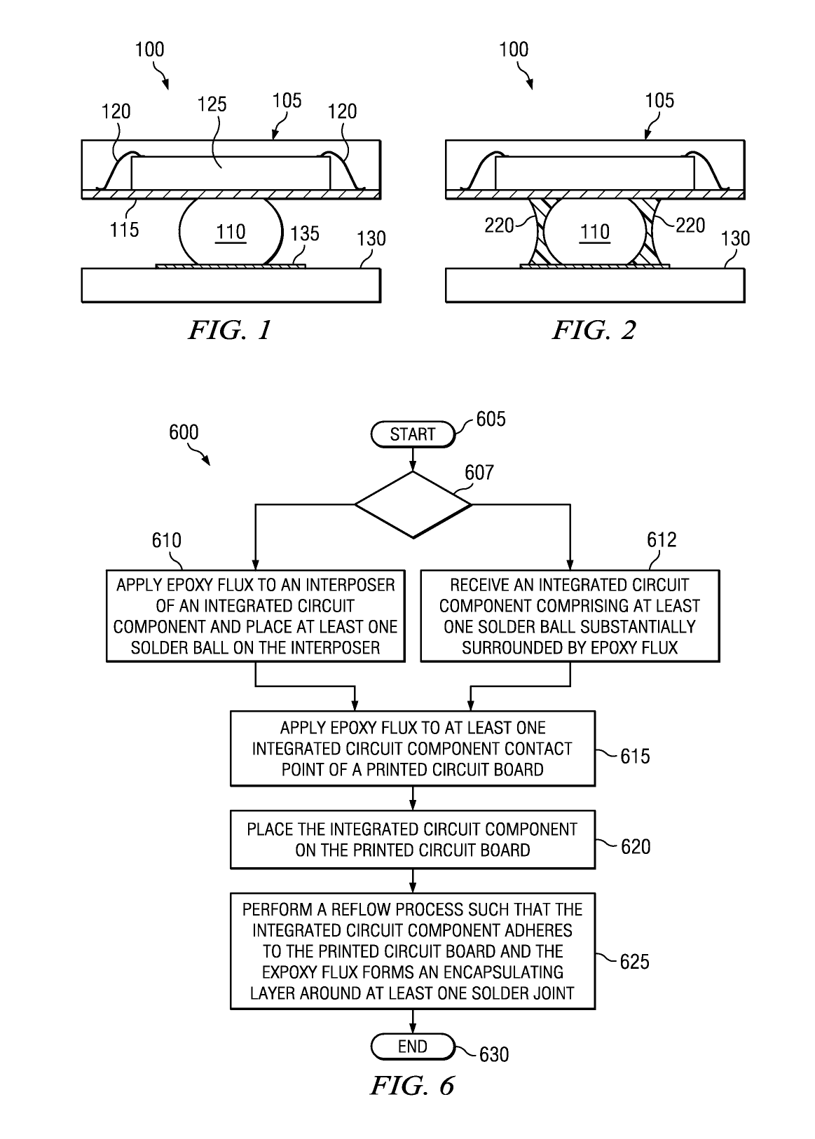

An example embodiment of the present invention and its potential advantages are understood by referring to FIGS. 1 through 6 of the drawings.

FIG. 1 is a block diagram of an apparatus 100 comprising an integrated circuit component 105, printed circuit board 130 and a solder joint 110 coupling the integrated circuit component 105 and printed circuit board 130 according to an example embodiment of the invention. In an embodiment, the integrated circuit component 105 is a wire bonded chip scale package, however, any type of chip scale package may used including but not limited to flip-chip, non-flip-chip, ball grid array packages and/or the like. In an embodiment, a wire bonded chip scale package is a single-die, direct surface mountable integrated circuit package generally comprising a die such as die 125 mounted on an interposer such as interposer 115 using nonconductive epoxy. In an embodiment, die 125 is wire bonded to the interposer using gold or aluminum wires such as wires 120. At least one solder ball is affixed to the bottom side of the interposer 115 providing the integrated circuit component with an electrical and mechanical connection to a printed circuit board such as printed circuit board 130. In an embodiment, during a process known in art as a reflow process, the integrated circuit component is physically and electrically coupled with at least one integrated circuit contact point on a printed circuit board such as integrated circuit contact point 135. In an embodiment, a reflow process is a soldering process in which solder paste is used to temporarily attach one or more electrical components to their contact points on a printed circuit board, after which the assembly is subjected to controlled heat, which melts the solder permanently connecting the solder joints. In an embodiment, an integrated circuit contact point is a solder pad.

FIG. 2 is a block diagram of the apparatus 100 of FIG. 1 further comprising the solder joint 110 being encapsulated by epoxy flux 220 according to an example embodiment of the invention. In an embodiment, epoxy flux such as Epoxy Flux available from Indium Corporation of America of 1676 Lincoln Avenue, Utica, N.Y. 13502, is a product combining the properties of solder flux and epoxy for ribbon connector surface mount technology applications as well as ball grid array and chip scale packages.

According to FIG. 2, in an embodiment, epoxy flux substantially surrounds and/or encapsulates solder joint 110 providing for a more mechanically reliable solder joint. Further, epoxy flux 220 adheres to integrated circuit component 105, solder joint 110 and printed circuit board 130 further protecting the solder joint 110 from mechanical vibration and stress. In an embodiment, epoxy flux is non-conductive. In another embodiment, epoxy flux is conductive.

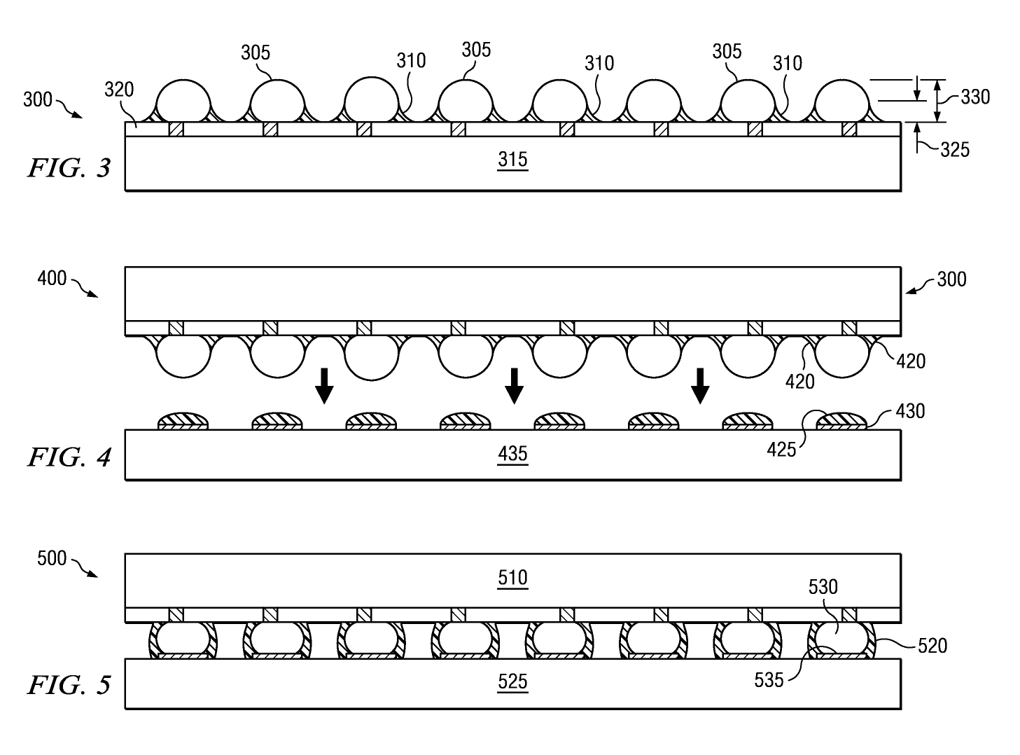

FIG. 3 is a block diagram of an integrated circuit component 300 comprising a plurality of solder balls such as solder balls 305 substantially surrounded by epoxy flux 310 according to an example embodiment of the invention. In an embodiment, integrated circuit component 300 is at least one of a chip scale package, surface mount component, wafer level chip scale package, application specific integrated passive, application specific instruction processor, package-on-package component and/or the like. However, integrated circuit component 300 may be any type of surface mounted integrated circuit component. In an embodiment, a solder ball is a volume of solder substantially in a shape of a small sphere, which provides an electrical and mechanical connection between an integrated circuit component and a printed circuit board. In an embodiment, a solder ball is a solder sphere.

In an embodiment, during manufacturing of an integrated circuit component, epoxy flux is applied to the integrated circuit component interposer such as interposer 320 prior to placement of each solder ball. The epoxy flux can be placed on the integrated circuit component by any process known to those skilled in the art such as but not limited to jetting, pin transfer, stencil printing and/or the like. In an embodiment, after epoxy flux is applied to the integrated circuit component interposer, solder balls may be placed on the interposer in a process known to those skilled in the art as ball bumping. In an embodiment, once solder balls are placed on the integrated circuit component interposer, a reflow process takes place in which the epoxy flux forms an encapsulating layer substantially surrounding each solder ball as shown in FIG. 3. In an embodiment, after the reflow process, the height of the epoxy flux 325 is approximately 50% of the solder ball height 330 as depicted in FIG. 3.

FIG. 4 is a block diagram of the integrated circuit component 300 of FIG. 3 and a printed circuit board 435 having at least one integrated circuit contact point such as integrated circuit contact point 430 with epoxy flux 425 disposed thereon according to an example embodiment of the invention. In an embodiment, an integrated circuit contact point on a printed circuit board is also known as a solder pad. In an embodiment, prior to placement of integrated circuit component 300 on printed circuit board 435, epoxy flux is applied to at least one integrated circuit contact point such as 430 on printed circuit board 435. In an embodiment, the volume of epoxy flux, which is applied to an integrated circuit contact point, is related to the size of integrated circuit contact point.

FIG. 5 is a block diagram of an apparatus, the apparatus comprising an integrated circuit component 510 comprising at least one solder joint coupled with a printed circuit board, the at least one solder joint being substantially encapsulated by epoxy flux according to an example embodiment of the invention. In an embodiment, integrated circuit component 510 is at least one of a chip scale package, surface mount component, wafer level chip scale package, application specific integrated passive, application specific instruction processor and/or the like. In an embodiment, after a reflow process, epoxy flux such as epoxy flux 520 forms a protective layer around and substantially encapsulates solder joint 530 providing for improved mechanical reliability. Further, epoxy flux 520 adheres to integrated circuit contact points such as integrated circuit contact point 535 on printed circuit board, solder joint 530 and integrated circuit component 510 further protecting the solder joint 530 from mechanical vibration and stress. In an embodiment, epoxy flux is non-conductive. In another embodiment, epoxy flux is conductive. In an embodiment, integrated circuit component 510 is integrated circuit component 300 of FIG. 3.

FIG. 6 is a flow diagram 600 illustrating a method for coupling at least one integrated circuit component with a printed circuit board according to an example embodiment of the invention. The method begins at 605. At 607, a determination is made to proceed to 612 if an integrated circuit component comprising at least one solder ball surrounded by epoxy flux will be received. Otherwise, 610 is executed.

At 610, epoxy flux is applied to an interposer of an integrated circuit component such as interposer 320 of FIG. 3. The epoxy flux may be placed on the integrated circuit component by any process known to those skilled in the art such as but not limited to jetting, pin transfer, stencil printing and/or the like. Further, at 610, at least one solder ball is placed on the interposer. In an embodiment, solder balls are placed on the interposer in a process known to those skilled in the art as ball bumping. In an embodiment, once solder balls are placed on the integrated circuit component interposer, a reflow process takes place in which the epoxy flux forms an encapsulating layer substantially surrounding each solder ball as shown in FIG. 3. In an embodiment, after the reflow process, the height of the epoxy flux such as epoxy flux 325 of FIG. 3 is approximately 50% of the solder ball height 330. In an embodiment, epoxy flux is applied prior to ball placement. In an embodiment, an integrated circuit component is at least one of a chip scale package, surface mount component, wafer level chip scale package, application specific integrated passive, application specific instruction processor and/or the like. In an embodiment, epoxy flux is non-conductive. In another embodiment, epoxy flux is conductive.

Alternatively, at 612, an integrated circuit component such as integrated circuit component 300 of FIG. 3 comprising at least one solder ball substantially surrounded by epoxy flux is received. In an embodiment, the integrated circuit component is at least one of a chip scale package, surface mount component, wafer level chip scale package, application specific integrated passive, application specific instruction processor and/or the like. In an embodiment, integrated circuit component is integrated circuit component 300 of FIG. 3. In an embodiment, the integrated circuit component is received by a circuit board manufacturer from an integrated circuit component manufacturer. For example, the circuit board manufacturer may be a company that produces circuit boards for mobile computers, communication devices and/or the like. In an embodiment, epoxy flux is non-conductive. In another embodiment, epoxy flux is conductive.

At 615, epoxy flux is applied to at least one integrated circuit component contact point of a printed circuit board such as integrated circuit component contact points 430 of FIG. 4. Any manufacturing process known in the art, which is capable of applying epoxy flux to a printed circuit board, may be used including but not limited to jetting. In an embodiment, epoxy flux is applied to the at least one integrated circuit component contact point prior to integrated circuit component placement on the printed circuit board. In an embodiment, the integrated circuit component is integrated circuit component 300 of FIG. 3. In an embodiment, an integrated circuit component contact point of a printed circuit board is a solder pad. In an embodiment, epoxy flux is non-conductive. In another embodiment, epoxy flux is conductive.

In an embodiment, a volume of epoxy flux, which is applied to the at least one integrated circuit component contact point is related to the at least one solder ball size of the integrated circuit component. For example, a larger solder ball size on an integrated circuit component may require a larger volume of epoxy flux on the corresponding integrated circuit component solder pads.

At 620, the integrated circuit component is placed in position on the corresponding solder pads of the printed circuit board such as in assembly 500 of FIG. 5. Placement of surface mounted integrated circuit components is well known in the art circuit board manufacturers. In an embodiment, an integrated circuit component is placed in position on corresponding solder pads of a printed circuit board using a high-speed, high precision, robotic circuit component placement machine.

At 625, a reflow process is performed such that the integrated circuit component adheres to the corresponding solder pads of the printed circuit board. Further, during the reflow process, the epoxy flux previously applied to the base of the integrated circuit solder balls and to the solder pads on the printed circuit board forms an encapsulating layer surrounding at least one solder joint. The encapsulating layer of epoxy flux surrounding each solder joint of the integrated circuit provides protective layer, which reduces mechanical stress and increases the mechanical reliability of each solder joint.

Without in any way limiting the scope, interpretation, or application of the claims appearing below, a technical effect of one or more of the example embodiments disclosed herein is to provide a solder joint, which has improved mechanical reliability and a better tolerance of mechanical stress.

If desired, the different functions and/or methods discussed herein may be performed in a different order and/or concurrently with each other. Furthermore, if desired, one or more of the above-described functions may be optional or may be combined.

Although various aspects of the invention are set out in the independent claims, other aspects of the invention comprise other combinations of features from the described embodiments and/or the dependent claims with the features of the independent claims, and not solely the combinations explicitly set out in the claims.

It is also noted herein that while the above describes example embodiments of the invention, these descriptions should not be viewed in a limiting sense. Rather, there are several variations and modifications which may be made without departing from the scope of the present invention as defined in the appended claims.

What is claimed is:

1. A method, comprising:
receiving an integrated circuit component comprising at least one solder ball substantially surrounded by a first epoxy flux;
applying a second epoxy flux to at least one integrated circuit component contact point of a printed circuit board; and
performing a reflow process such that said integrated circuit component adheres to said printed circuit board and said first and second epoxy flux forms an encapsulating layer around at least one solder joint.

2. A method according to claim 1, wherein said second epoxy flux is applied to said at least one integrated circuit component contact point by jetting.

3. A method according to claim 1, wherein said integrated circuit component is at least one of a surface mount component, chip scale package, wafer level chip scale package, application specific integrated passive, application specific instruction processor and package-on-package component.

4. A method according to claim 1, further comprising placing said integrated circuit component on said printed circuit board.

5. A method according to claim 4, wherein said applying said second epoxy flux occurs prior to said placing said integrated circuit component on said printed circuit board.

6. A method according to claim 1, wherein said applying said second epoxy flux is performed prior to said reflow process.

7. A method according to claim 1, wherein said epoxy flux is non-conductive.

8. A method, comprising:
applying epoxy flux to an interposer of an integrated circuit component; and
placing at least one solder ball on said interposer.

9. A method according to claim 8, wherein said applying epoxy flux to said interposer is performed by jetting.

10. A method according to claim 8, further comprising applying epoxy flux to at least one integrated circuit component contact point of a printed circuit board.

11. A method according to claim 10, further comprising placing said integrated circuit component on a printed circuit board.

12. A method according to claim 11, further comprising performing a reflow process such that said integrated circuit component adheres to said printed circuit board and said epoxy flux forms an encapsulating layer around at least one solder joint.

13. A method according to claim 12, wherein said reflow process is performed subsequent to said placing said integrated circuit component on said printed circuit board.

14. A method according to claim 12, wherein said reflow process is performed subsequent to applying epoxy flux to at least one integrated circuit component contact point of a printed circuit board.

15. A method according to claim 8, wherein a volume of said epoxy is related to a size of said at least one solder ball.

16. A method according to claim 8, wherein said integrated circuit component is at least one of a surface mount component, chip scale package, wafer level chip scale package, application specific integrated passive, application specific instruction processor and package-on-package component.

17. A method according to claim 8, wherein said epoxy flux is non-conductive.

18. An apparatus, comprising:
an integrated circuit component comprising at least one solder joint coupled with a printed circuit board, said solder joint being substantially encapsulated by epoxy flux.

19. An apparatus according to claim 18, wherein said at least one integrated circuit component is at least one of a surface mount component, chip scale package, wafer level chip scale package, application specific integrated passive, application specific instruction processor and package-on-package component.

20. An apparatus according to claim 18, wherein said epoxy flux is non-conductive.
